(19) United States
(12) Patent Application Publication
(10) Pub. No.: US 2025/0143138 A1
(43) Pub. Date: May 1, 2025

(54) DISPLAY DEVICE AND METHOD OF MANUFACTURING THE SAME

(71) Applicant: Samsung Display Co., LTD., Yongin-si (KR)

(72) Inventors: Seoulki LEE, Yongin-si (KR); Hwi KIM, Yongin-si (KR); Jungsun PARK, Yongin-si (KR); Jihee SON, Yongin-si (KR); Seungjun LEE, Yongin-si (KR); Areum LEE, Yongin-si (KR); Yeonhwa LEE, Yongin-si (KR); Joongu LEE, Yongin-si (KR)

(21) Appl. No.: 18/663,696

(22) Filed: May 14, 2024

(30) Foreign Application Priority Data
Oct. 25, 2023 (KR) 10-2023-0144177

(51) Int. Cl. H10K 59/80; H10K 71/60; H10K 102/00

(52) U.S. Cl. CPC H10K 59/8052; H10K 71/60; H10K 2102/351

(57) ABSTRACT

Provided is a display device and a method of manufacturing the display device. The display device includes a substrate, a pixel electrode disposed on the substrate, an intermediate layer disposed on the pixel electrode, and a common electrode disposed on the intermediate layer. The common electrode includes a silver (Ag) material doped with a first metal.

### CROSS-REFERENCE TO RELATED APPLICATION

This application claims priority to Korean Patent Application No. 10-2023-0144177, filed on Oct. 25, 2023, and all the benefits accruing therefrom under 35 U.S.C. § 119, the content of which in its entirety is herein incorporated by reference.

### BACKGROUND

### 1. Field

One or more embodiments relate to devices and methods, and more particularly, to a display device and a method of manufacturing a display device.

### 2. Description of the Related Art

Mobile electronic devices are currently widely used. In addition to compact electronic devices such as, for example, mobile phones, tablet personal computers (PCs) have recently been widely used as mobile electronic devices.

Some mobile electronic devices may include a display device to support various functions and provide visual information such as, for example, images or video to users. Recently, as other components for driving display devices have decreased in size, the proportion of the display devices in electronic devices to the other components is gradually increasing, and structures that are bendable according to a predetermined angle from a flat state are also being developed.

### SUMMARY

One or more embodiments include a common electrode which includes a silver (Ag) material doped with a first metal. The common electrode includes particles in which the silver (Ag) material and the first metal are combined.

However, the objective is an example, and the objectives to be solved by the disclosure are not limited thereto.

Additional aspects will be set forth in part in the description which follows and, in part, will be apparent from the description, or may be learned by practice of the presented embodiments of the disclosure.

According to one or more embodiments, a display device includes a substrate, a pixel electrode disposed on the substrate, an intermediate layer disposed on the pixel electrode, and a common electrode disposed on the intermediate layer, wherein the common electrode includes a silver (Ag) material doped with a first metal.

The display device may further include a capping layer disposed on the common electrode.

The first metal may include at least one material among aluminum (Al) and copper (Cu).

A doping concentration of the first metal may range from about 5% to about 20%.

A thickness of the common electrode may be about 0.01 μm to about 10 μm.

The common electrode may include particles in which the silver (Ag) material and the first metal are combined.

A path of light emitted from the intermediate layer may be changed as the light is incident the particles.

The particles may be uniformly distributed in the common electrode.

According to one or more embodiments, a method of manufacturing a display device includes disposing a pixel electrode on a substrate, disposing an intermediate layer on the pixel electrode, and disposing a common electrode on the intermediate layer, wherein the disposing of the common electrode includes spraying a silver (Ag) material on the intermediate layer, and spraying a first metal onto the intermediate layer.

A spray rate of the first metal may range from about 0.61 Å/s to about 1 Å/s.

The method may further include disposing a capping layer on the common electrode.

The first metal may include at least one material among aluminum (Al) and copper (Cu).

A doping concentration of the first metal may range from about 5% to about 20%.

A thickness of the common electrode may range from about 0.01 μm to about 10 μm.

The silver (Ag) material and the first metal may combine to form particles.

A path of light emitted from the intermediate layer may be changed as the light is incident the particles.

The particles may be uniformly distributed in the common electrode.

Other aspects, features and advantages in addition to those described herein will become apparent from the following drawings, claims, and detailed description of the example embodiments supported by the present disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view schematically illustrating a display device according to an embodiment;

FIG. 2 is a cross-sectional view schematically illustrating a display device according to an embodiment;

FIG. 3 is an equivalent circuit diagram of any one pixel of a display device according to an embodiment;

FIG. 4 is a cross-sectional view schematically illustrating a display device according to an embodiment;

FIG. 5 is a graph illustrating an example first condition for forming a common electrode;

FIG. 6 illustrates a cross-sectional view schematically illustrating a display device including a common electrode formed according to the first condition and experimental data;

FIG. 7 is a graph illustrating an example second condition for forming a common electrode; and

FIG. 8 illustrates a cross-sectional view schematically illustrating a display device including a common electrode formed according to the second condition and experimental data.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described herein, by referring to the figures, to explain aspects of the present description. As used herein, the term “and/or” includes any and all combinations of one or more of the associated listed items. Throughout the disclosure, the expression “at least one of a, b and c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. The effects and features of the disclosure, and ways to achieve them will become apparent by referring to embodiments that will be described later in detail with reference to the drawings. However, the disclosure is not limited to the following embodiments but may be embodied in various forms.

Hereinafter, embodiments of the disclosure will be described in detail with reference to the accompanying drawings, and in the description with reference to the drawings, like reference numerals refer to like elements and redundant descriptions thereof will be omitted.

It will be understood that although the terms “first,” “second,” and the like may be used herein to describe various elements, the elements should not be limited by these terms. These terms are used to distinguish one element from another.

Singular expressions, unless defined otherwise in contexts, may include plural expressions.

In the following embodiments, terms such as, for example, include or have mean that the features or elements described in the specification exist, and do not exclude in advance implementations of adding one or more other features or elements.

In the embodiments herein, it will be understood when a portion such as, for example, a layer, an area, or an element is referred to as being “on” or “above” another portion, the portion can be directly on or above the other portion, or an intervening portion may also be present.

Also, in the drawings, for convenience of description, sizes of elements may be exaggerated or contracted. For example, sizes and thicknesses of elements in the drawings are arbitrarily illustrated for convenience of explanation, and the following embodiments are not limited thereto.

In the embodiments herein, an x-axis, a y-axis, and a z-axis are not limited to three axes on a rectangular coordinates system but may be construed as including these axes. For example, an-x axis, a y-axis, and a z-axis may be at right angles or may also indicate different directions from one another, which are not at right angles.

When an embodiment is implementable in another manner, a predetermined process order may be different from a described one. For example, two processes that are consecutively described may be substantially simultaneously performed or may be performed in an opposite order to the described order.

The term “substantially,” as used herein, means approximately or actually. The term “substantially equal,” as used herein, means approximately or actually equal (e.g., within a threshold percent of equal). The term “substantially the same,” as used herein, means approximately or actually the same (e.g., within a threshold difference amount). The term “substantially simultaneously,” as used herein, means approximately or actually at the same time.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

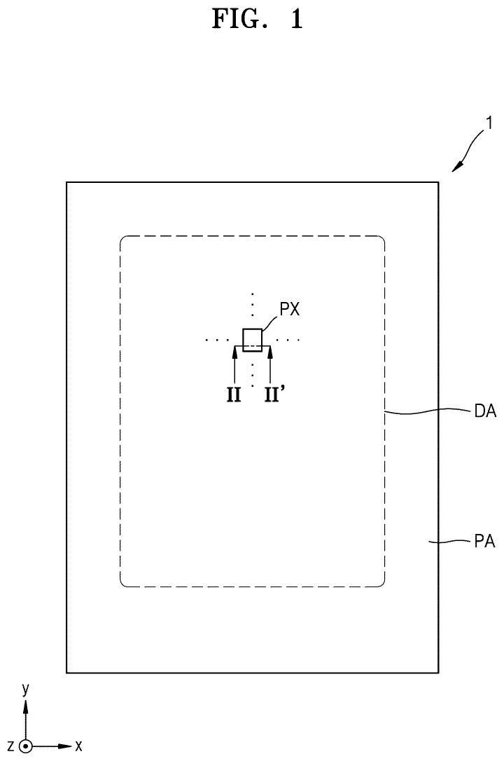

FIG. 1 is a plan view schematically illustrating a display device 1 according to an embodiment.

Referring to FIG. 1, the display device 1 manufactured according to an embodiment may include a display area DA and a peripheral area PA located outside the display area DA. The display device 1 may provide an image through an array of a plurality of pixels PX arranged two-dimensionally in the display area DA.

In some embodiments, the peripheral area PA is an area that does not provide an image, and the peripheral area PA may completely or partially surround the display area DA. The display device 1 may include, arranged in the peripheral area PA, a driver, or the like, for providing an electrical signal or power to pixel circuits respectively corresponding to the pixels PX. The display device 1 may include, arranged in the peripheral area PA, a pad which is an area, to which an electronic element or a printed circuit board may be electrically connected.

Hereinafter, the display device 1 is described as including an organic light-emitting diode OLED as a light-emitting element in accordance with one or more embodiments of the present disclosure. However, embodiments of the display device 1 are not limited thereto. As another example, the display device 1 may be a light-emitting display device including an inorganic light-emitting diode, that is, an inorganic light-emitting display. The inorganic light-emitting diode may include a PN junction diode including inorganic semiconductor-based materials. When a voltage is applied to the PN junction diode in a forward direction, holes and electrons are injected, and energy generated by recombination of the holes and electrons is converted into light energy to emit light of a certain color. The inorganic light-emitting diode described herein may have a width of several to hundreds of micrometers, and in some embodiments, the inorganic light-emitting diode may be referred to as a micro light-emitting diode (LED). In one or more other embodiments, the display device 1 may be a quantum dot light-emitting display.

The display device 1 may be used in portable electronic devices such as, for example, a mobile phone, a smart phone, a tablet personal computer (PC), a mobile communication terminal, an electronic notebook, an e-book, a portable multimedia player (PMP), a navigation device, a ultra mobile personal computer (UMPC), and also as a display screen for various products such as, for example, televisions, laptops, monitors, billboards, and Internet of Things (IOT) devices. In addition, the display device 1 according to an embodiment may be used in a wearable device such as, for example, a smart watch, a watch phone, a glasses-type display, and a head mounted display (HMD). Further, the display device 1 according an embodiment may be used as a center information display (CID) arranged on an instrument panel of a vehicle, a center fascia, or a dashboard of a vehicle, a room mirror display functioning in place of a side view mirror of a vehicle, and a display arranged on the back of a front seat as an entertainment element for a rear seat of a vehicle.

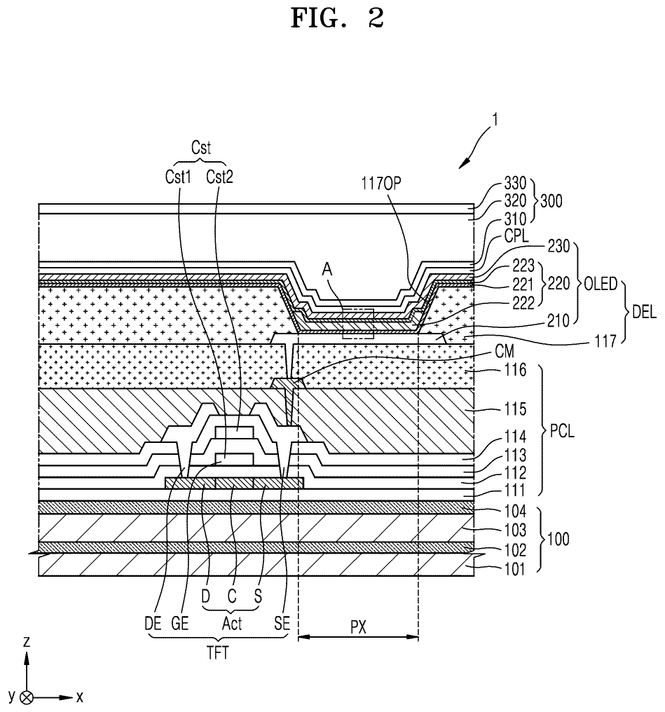

FIG. 2 is a cross-sectional view schematically illustrating the display device 1 according to an embodiment and may correspond to a cross-section of the display device 1 taken along line II-II′ of FIG. 1.

Referring to FIG. 2, the display device 1 may include a stacked structure of a substrate 100, a pixel circuit layer PCL, a display element layer DEL, a capping layer CPL, and an encapsulation layer 300.

The substrate 100 may have a multilayer structure including a base layer including a polymer resin and an inorganic layer. For example, the substrate 100 may include a base layer including a polymer resin and a barrier layer of an inorganic insulating layer. For example, the substrate 100 may include a first base layer 101, a first barrier layer 102, a second base layer 103, and a second barrier layer 104 that are sequentially stacked. The first base layer 101 and the second base layer 103 may include polyimide (PI), polyethersulfone (PES), polyarylate, polyether imide (PEI), polyethylene napthalate (PEN), polyethyeleneterepthalate (PET), polyphenylene sulfide (PPS), polycarbonate, cellulose triacetate (TAC), and/or cellulose acetate propionate (CAP). The first barrier layer 102 and the second barrier layer 104 may include an inorganic insulating material such as, for example, silicon oxide, silicon oxynitride, and/or silicon nitride. The substrate 100 may be flexible.

The pixel circuit layer PCL is disposed on the substrate 100. FIG. 2 illustrates the pixel circuit layer PCL including a thin-film transistor TFT and a buffer layer 111, a first gate insulating layer 112, and a second gate insulating layer 113, an interlayer insulating layer 114, a first planarization insulating layer 115, and a second planarization insulating layer 116, which are disposed under and/or on components of the thin-film transistor TFT.

The buffer layer 111 may reduce or block foreign substances, moisture, or external air from penetrating (e.g., penetrating below) the substrate 100 and may provide a flat surface on the substrate 100. The buffer layer 111 may include an inorganic insulating material such as, for example, silicon oxide, silicon oxynitride, or silicon nitride, and may have a single-layer or multi-layer structure including one or more of the inorganic insulating materials.

The thin-film transistor TFT on the buffer layer 111 may include a semiconductor layer Act, and the semiconductor layer Act may include poly-silicon (poly-Si). Alternatively, or additionally, the semiconductor layer Act may include amorphous silicon (a-Si), an oxide semiconductor, an organic semiconductor, or the like. The semiconductor layer Act may include a channel region C. The semiconductor layer Act may include a drain region D and a source region S disposed on both sides of the channel region C, respectively. A gate electrode GE may overlap the channel region C.

The gate electrode GE may include a low-resistance metal material. The gate electrode GE may include a conductive material including molybdenum (Mo), aluminum (Al), copper (Cu), titanium (Ti), and the like, and the gate electrode GE may have a multi-layer or single-layer structure including the conductive material.

The first gate insulating layer 112 between the semiconductor layer Act and the gate electrode GE may include an inorganic insulating material such as, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may include zinc oxide (ZnO) and/or zinc peroxide (ZnO₂).

The second gate insulating layer 113 may be provided such that the second gate insulating layer 113 covers the gate electrode GE. Similar to the first gate insulating layer 112, the second gate insulating layer 113 may include an inorganic insulating material such as, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may include zinc oxide (ZnO) and/or zinc peroxide (ZnO₂).

An upper electrode Cst2 of a storage capacitor Cst may be disposed on the second gate insulating layer 113. The upper electrode Cst2 may overlap the gate electrode GE disposed below the upper electrode Cst2. The gate electrode GE and the upper electrode Cst2 overlapping each other, with the second gate insulating layer 113 between the gate electrode GE and the upper electrode Cst2, may form the storage capacitor Cst. That is, the gate electrode GE may function as a lower electrode Cst1 of the storage capacitor Cst.

As described herein, the storage capacitor Cst and the thin-film transistor TFT may overlap each other. In some embodiments, the storage capacitor Cst may not overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and the upper electrode Cst2 may be a single layer or multiple layers including the materials described herein.

The interlayer insulating layer 114 may cover the upper electrode Cst2. The interlayer insulating layer 114 may include and inorganic insulating material such as, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may include zinc oxide (ZnO) and/or zinc peroxide (ZnO₂). The interlayer insulating layer 114 may include a single layer or a multilayer including the described inorganic insulating material.

The drain electrode DE and the source electrode SE may each be located on the interlayer insulating layer 114. The drain electrode DE and the source electrode SE may be connected to the drain region D and the source region S through contact holes formed in the insulating layers below the drain electrode DE and the source electrode SE, respectively. The drain electrode DE and source electrode SE may include a material with good conductivity (e.g., greater than or equal to a threshold conductivity value). The drain electrode DE and source electrode SE may include a conductive material including molybdenum (Mo), aluminum (Al), copper (Cu), titanium (Ti), or the like, and the drain electrode DE and source electrode SE may each be a multilayer or a single layer including the materials described herein. In an embodiment, the drain electrode DE and the source electrode SE may each have a multilayer structure of Ti/Al/Ti.

The first planarization insulating layer 115 may cover the drain electrode DE and the source electrode SE. The first planarization insulating layer 115 may include an organic insulating layer such as, for example, general-purpose polymers such as, for example, polymethylmethacrylate (PMMA) or polystyrene (PS), polymer derivatives having a phenolic group, acrylic polymers, imide polymers, aryl ether polymers, amide-based polymers, fluorine-based polymers, p-xylene-based polymers, vinyl alcohol-based polymers, and blends of the general-purpose polymers.

The second planarization insulating layer 116 may be disposed on the first planarization insulating layer 115. The second planarization insulating layer 116 may include the same material as the first planarization insulating layer 115, and the second planarization insulating layer 116 may include an organic insulating layer such as, for example, general-purpose polymers such as, for example, polymethylmethacrylate (PMMA) or polystyrene (PS), polymer derivatives having a phenolic group, acrylic polymers, imide polymers, aryl ether polymers, amide-based polymers, fluorine-based polymers, p-xylene-based polymers, vinyl alcohol-based polymers, and blends of the general-purpose polymers.

The display element layer DEL may be disposed on the pixel circuit layer PCL of the described structure. The display element layer DEL may include an organic light-emitting diode OLED as a display element (i.e., a light-emitting element), and the organic light-emitting diode OLED may include a stacked structure including a pixel electrode 210, an intermediate layer 220, and a common electrode 230. The organic light-emitting diode OLED, for example, may emit red, green, or blue light, or may emit red, green, blue, or white light. The organic light-emitting diode OLED emit light through a light-emitting area, and the light-emitting area may be defined as a pixel PX.

The pixel electrode 210 of the organic light-emitting diode OLED may be electrically connected to the thin-film transistor TFT through contact holes formed in the second planarization insulating layer 116 and the first planarization insulating layer 115 and a contact metal CM disposed on the first planarization insulating layer 115. That is, for example, the pixel electrode 210 may be disposed on the substrate 100.

The pixel electrode 210 may include a conductive oxide such as, for example, indium tin oxide (ITO), indium zinc oxide (IZO), zinc oxide (ZnO), indium oxide (In₂O₃), indium gallium oxide (IGO), or aluminum zinc oxide (AZO). In one or more other embodiments, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In one or more other embodiments, the pixel electrode 210 may have a structure in which layers including ITO, IZO, ZnO or In₂O₃ are above or below the described reflective layer.

A bank layer 117 having an opening 117OP exposing a central portion of the pixel electrode 210 may be disposed on the pixel electrode 210. The bank layer 117 may include an organic insulating material and/or an inorganic insulating material. The opening 117OP may define a light-emitting area of light emitted from the organic light-emitting diode OLED. For example, the size/width of the opening 117OP may correspond to a size/width of the light-emitting area. Accordingly, the size and/or width of the pixel PX may be based on or may correspond to the size and/or width of the opening 117OP of a corresponding bank layer 117.

The intermediate layer 220 may include an emission layer 222 formed to correspond to the pixel electrode 210. The emission layer 222 may include a polymer or low-molecular organic material, which emits light of a certain color. Alternatively, or additionally, the emission layer 222 may include an inorganic light-emitting material or quantum dots. That is, the intermediate layer 220 may be disposed on the pixel electrode 210 and emit light.

In an embodiment, the intermediate layer 220 may include a first functional layer 221 and a second functional layer 223 disposed below and above the emission layer 222, respectively. For example, the first functional layer 221 may include a hole transport layer HTL, or the first functional layer 221 may include a hole transport layer HTL and a hole injection layer HIL. The second functional layer 223 is a component disposed on the emission layer 222 and may include an electron transport layer ETL and/or an electron injection layer EIL. The first functional layer 221 and/or the second functional layer 223 may include a common layer formed such that the common layer entirely covers the substrate 100, similar to the common electrode 230, which will be described later.

The common electrode 230 may be disposed on the pixel electrode 210 and overlap the pixel electrode 210. The common electrode 230 may be disposed on the intermediate layer 220. The common electrode 230 may include a conductive material having a low work function (e.g., at or below a threshold work function). For example, the common electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, or additionally, the common electrode 230 may include a layer such as, for example, ITO, IZO, ZnO, or In₂O₃ on the (semi) transparent layer including the described material. The common electrode 230 may be formed integrally such that the common electrode 230 covers the entire substrate 100.

The capping layer CPL may be disposed on the display element layer DEL and cover the display element layer DEL. That is, the capping layer CPL may be disposed on the common electrode 230. The capping layer CPL may have a higher refractive index than a refractive index of the common electrode 230. For example, the capping layer CPL may have a refractive index of about 1.9 to about 2.3 at a wavelength of about 530 nm. A thickness of the capping layer CPL may range from about 600 Å to about 900 Å. Preferably, the thickness of the capping layer CPL may range from about 600 Å to about 750 Å.

In the disclosure, a capping layer CPL having a relatively high refractive index may be disposed on the common electrode 230, and due to the capping layer CPL, the reflectance of light emitted from the intermediate layer 220, from the common electrode, 230 may increase. Accordingly, the resonance efficiency of a micro-resonance structure is improved, thereby increasing the light extraction efficiency of the organic light-emitting diode OLED.

Here, reflection from the common electrode 230 may be a concept that refers to reflection from a lower surface of the common electrode 230. The reflection from the common electrode 230 may also refer to reflection at an interface between the common electrode 230 and the capping layer CPL or an interface between the capping layer CPL and the encapsulation layer 300.

According to an embodiment, the capping layer CPL may include a triamine derivative, a carbazole biphenyl derivative, an arylenediamine derivative, aluminum quinoleum complex (Alq3), or the like. Aspects of the present disclosure support adjusting the composition of the derivative and/or one or more other properties of the derivative, in association with implementing a material having a refractive index according to the wavelength as described herein.

The encapsulation layer 300 may be disposed on the capping layer CPL. That is, the encapsulation layer 300 may be disposed on the display element layer DEL and cover the display element layer DEL. The encapsulation layer 300 may include at least one inorganic encapsulation layer and at least one organic encapsulation layer. As an embodiment, the encapsulation layer 300 described with reference to FIG. 2 may include a first inorganic encapsulation layer 310, an organic encapsulation layer 320, and a second inorganic encapsulation layer 330, which are sequentially stacked.

The first inorganic encapsulation layer 310 and the second inorganic encapsulation layer 330 may include at least one inorganic material selected from aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include an acrylic resin, an epoxy-based resin, polyimide, polyethylene, and the like. In an embodiment, the organic encapsulation layer 320 may include acrylate. The organic encapsulation layer 320 may be formed by curing a monomer or applying a polymer. The organic encapsulation layer 320 may be transparent.

Although not illustrated, a touch sensor layer may be disposed on the encapsulation layer 300, and an optical functional layer may be disposed on the touch sensor layer. Using the touch sensor layer, coordinate information according to an external input, for example, a touch event may be obtained. The optical functional layer may reduce the reflectance of light (external light) incident from the outside toward a display device and/or improve the color purity of light emitted from the display device. In an embodiment, the optical functional layer may include a phase retarder and/or a polarizer. The phase retarder may include be a film type or a liquid crystal coating type, and the phase retarder may include a λ/2 phase retarder and/or a λ/4 phase retarder. The polarizer may be a film type or a liquid crystal coating type. The film type polarizer may include a stretched synthetic resin film, and the liquid crystal coating type polarizer may include liquid crystals arranged in a certain arrangement. The phase retarder and the polarizer may further include a protective film.

An adhesive member may be arranged between the touch electrode layer and the optical function layer. The adhesive member may be any general material known in the art without limitation. The adhesive member may be a pressure sensitive adhesive (PSA).

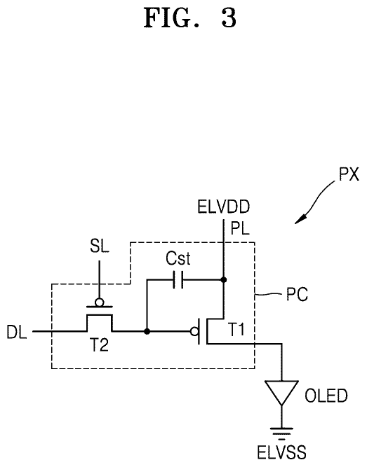

FIG. 3 is an equivalent circuit diagram of any one pixel PX of the display device 1 according to an embodiment.

Each pixel PX may include a pixel circuit PC and a display element connected to the pixel circuit PC, for example, an organic light-emitting diode OLED. The pixel circuit PC may include a first thin-film transistor T1, a second thin-film transistor T2, and a storage capacitor Cst. Each pixel PX may emit, for example, red, green, blue or white light through the organic light-emitting diode OLED.

The second thin-film transistor T2 may be a switching thin-film transistor and may be connected to a scan line SL and a data line DL. The second thin-film transistor T2 may be configured to transmit a data voltage input from the data line DL based on a switching voltage input from the scan line SL, to the first thin-film transistor T1. The storage capacitor Cst may be connected to the second thin-film transistor T2 and a driving voltage line PL. The storage capacitor Cst may store a voltage corresponding to a difference between a voltage received from the second thin-film transistor T2 and a first power voltage ELVDD supplied to the driving voltage line PL.

The first thin-film transistor T1 may be a driving thin-film transistor and may be connected to the driving voltage line PL and the storage capacitor Cst. The first thin-film transistor T1 may control a driving current flowing through the organic light-emitting diode OLED from the driving voltage line PL, in response to a voltage value stored at the storage capacitor Cst. The organic light-emitting diode OLED may emit light having a certain luminance according to a driving current. A common electrode (e.g., cathode) of the organic light-emitting diode OLED may receive a second power voltage ELVSS.

While the pixel circuit PC of FIG. 3 includes two thin-film transistors and one storage capacitor, the pixel circuit PC in accordance with embodiments of the present disclosure is not limited thereto. The number of thin-film transistors and the number of storage capacitors may vary based on the design of the pixel circuit PC. For example, the pixel circuit PC may include any suitable quantity of thin-film transistors and storage capacitors supportive of features of the pixel circuit PC. In some embodiments, the pixel circuit PC may include two thin-film transistors (as described herein with reference to FIG. 3), four thin-film transistors, or five or more thin-film transistors.

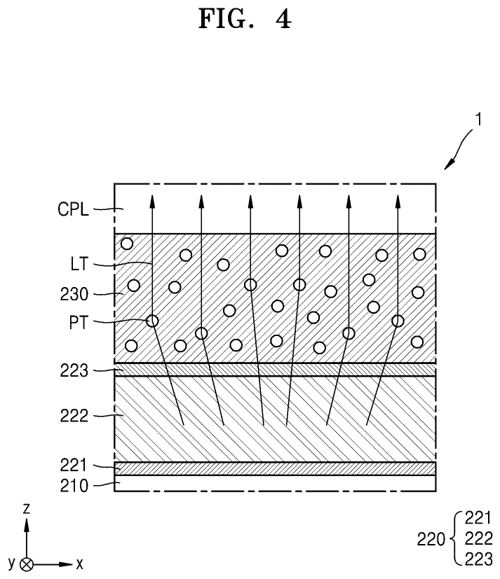

FIG. 4 is a cross-sectional view schematically illustrating the display device 1 according to an embodiment. In detail, FIG. 4 is an enlarged view of portion A of FIG. 2.

In FIG. 4, the same reference numerals as those of FIG. 2 refer to the same members, and repeated descriptions thereof will be omitted.

Referring to FIG. 4, the intermediate layer 220 may be disposed on the pixel electrode 210, the common electrode 230 may be disposed on the intermediate layer 220, and the capping layer CPL may be disposed on the common electrode 230. In detail, the intermediate layer 220 may include the first functional layer 221, the emission layer 222, and the second functional layer 223.

The common electrode 230 may include a silver (Ag) material doped with a first metal. The common electrode 230 may include particles PT in which the silver (Ag) material and the first metal are combined. For example, the particles PT may be formed of silver (Ag) and the first metal.

Accordingly, a path of light LT emitted from the intermediate layer 220 may change as the light is incident (e.g., comes into contact with) the particles PT of the common electrode 230. The light LT emitted from the intermediate layer 220 and dispersed may come into contact with the particles PT, and the path of the light LT may be changed in a direction perpendicular to a substrate (e.g., the substrate 100 in FIG. 2) (e.g., +z-axis direction). For example, due to contact with the particles PT, the change in the path of the light LT emitted from the intermediate layer 220 may reduce angle-dependent spectral distortion and resultant white angular dependency (WAD) associated with the display device 1. Accordingly, for example, the luminance and white angular dependency (WAD) characteristics of the display device 1 may be improved using a relatively simple process.

In an example, a portion of the light LT emitted from the intermediate layer 220 may travel in a direction which is not perpendicular to the substrate (e.g., a direction different from the +z-axis direction) prior to coming into contact with the particles PT, and the same portion of the light LT may travel in the direction perpendicular (e.g., +Z-axis direction) to the substrate after coming into contact with the particles PT.

In another example, a portion of the light LT emitted from the intermediate layer 220 may travel in the direction perpendicular (e.g., +z-axis direction) to the substrate prior to coming into contact with the particles PT, and the same portion of the light LT may travel in a direction which is not perpendicular to the substrate (e.g., a direction different from the +z-axis direction) after coming into contact with the particles PT.

The first metal may include at least one material from aluminum (Al) and copper (Cu). In an example in which the first metal includes an aluminum (Al) material, the common electrode 230 may include an AgAl material. In some aspects, a doping concentration of the first metal may range from about 5% to about 20%, and a thickness of the common electrode 230 may range from about 0.01 μm to about 10 μm.

The particles PT may be uniformly distributed in the common electrode 230. For example, the particles PT may be distributed in the common electrode 230 such that respective distances (e.g., in the x-direction, y-direction, and/or z-direction) between a particle PT and other particles PT adjacent the particle PT are substantially equal. However, aspects of the display device 1 as described with reference to FIG. 4 are examples, and the material of the first metal, the doping concentration of the first metal, and the thickness of the common electrode 230 are not limited thereto.

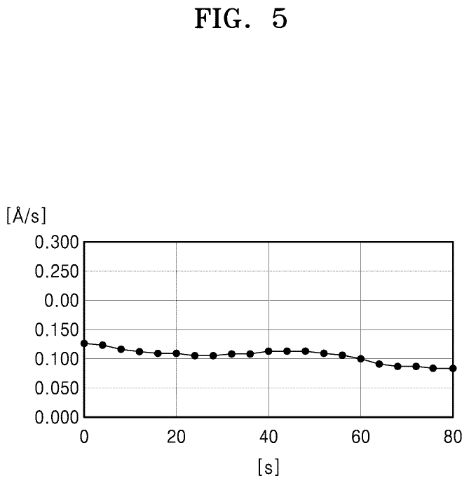

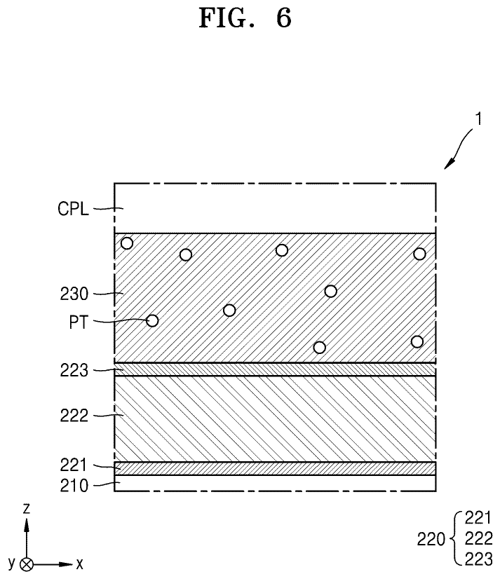

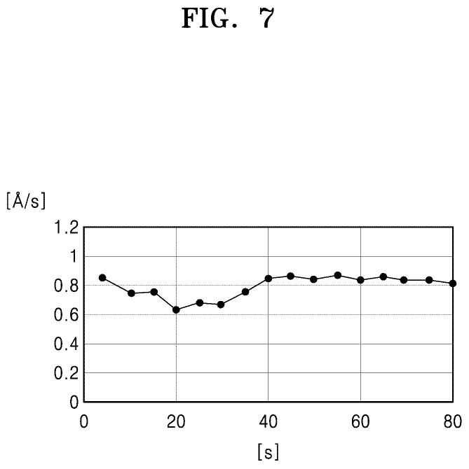

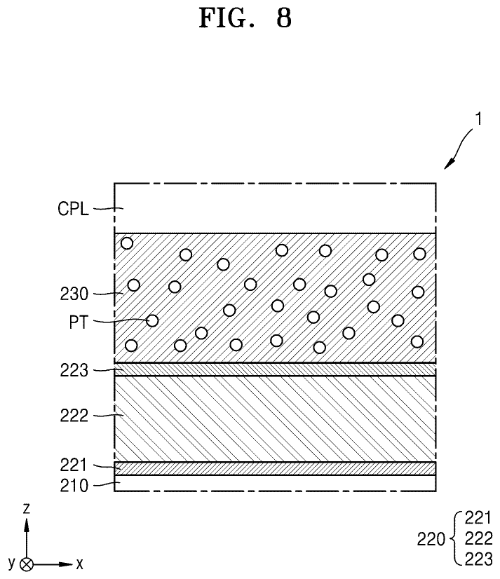

FIG. 5 is a graph illustrating an example first condition for forming the common electrode 230. FIG. 6 illustrates a cross-sectional view schematically illustrating the display device 1 including the common electrode 230 formed according to the first condition and experimental data. FIG. 7 is a graph illustrating an example second condition for forming the common electrode 230. FIG. 8 illustrates a cross-sectional view schematically illustrating the display device 1 including the common electrode 230 formed according to the second condition and experimental data. In detail, FIGS. 6 and 8 are enlarged views of portion A of FIG. 2.

In FIGS. 5 to 8, the same reference numerals as those of FIG. 2 refer to the same members, and repeated descriptions thereof will be omitted.

Referring to FIGS. 5 to 8, the intermediate layer 220 may be disposed on the pixel electrode 210, the common electrode 230 may be disposed on the intermediate layer 220, and the capping layer CPL may be disposed on the common electrode 230. In detail, the intermediate layer 220 may include the first functional layer 221, the emission layer 222, and the second functional layer 223.

A method of manufacturing the display device 1 in accordance with one or more embodiments of the present disclosure is described herein. The method may include disposing the pixel electrode 210 on a substrate (e.g., the substrate 100 in FIG. 2), disposing the intermediate layer 220 on the pixel electrode 210, disposing the common electrode 230 on the intermediate layer 220, and disposing the capping layer CPL on the common electrode 230.

In detail, the disposing of the common electrode 230 may include spraying a silver (Ag) material on the intermediate layer 220 and spraying a first metal (also referred to herein as a first metal material) on the intermediate layer 220. The sprayed silver (Ag) material may be doped with the sprayed first metal, and particles PT may be formed in the common electrode 230. That is, for example, the spraying of the first metal onto the silver (Ag) material may introduce impurities into the silver (Ag) material, modify properties of the silver (Ag) material, and/or form particles PT described herein. The spraying of the first metal onto the silver (Ag) material (and resultant doping of the silver (Ag) material with the first metal) may establish one or more properties (e.g., light transmittance properties, structural properties) of the resultant common electrode 230.

In the descriptions of the methods herein, the operations may be performed in a different order than the order described, or the operations may be performed in different orders or at different times. Certain operations may also be omitted, one or more operations may be repeated, or other operations may be added to the methods.

Referring to FIGS. 5 and 7, a horizontal axis represents the spray duration of an aluminum material, which is the first metal, and a vertical axis represents the spray rate (also referred to herein as spray speed) of the aluminum material, which is the first metal. In detail, the unit of measurement associated with the horizontal axis is seconds (sec), and the unit of measurement associated with the vertical axis is thickness per time (Å/s). The spray rate may refer to a rate at which a material (e.g., aluminum material, the first metal, or the like) is dispersed or sprayed onto a layer (e.g., intermediate layer 220).

Referring to FIG. 5, under the first condition, the spray rate of the aluminum material was set to about 0.05 Å/s to about 0.15 Å/s. In some aspects, referring to FIG. 7, under the first condition, the spray rate of the aluminum material was set to about 0.6 Å/s to about 1 Å/s. In another example, under the first condition, the spray rate of the aluminum material was set to about 0.61 Å/s to about 1 Å/s.

In both the first condition and the second condition, a thickness of the common electrode 230 was set to 100 Å and the doping concentration of the aluminum material was set to 10%.

That is, although not illustrated in FIGS. 5 and 7, the doping concentration of the aluminum material in the first condition and the second condition is the same, and the spray rate of the aluminum material is higher in the second condition than in the first condition, and thus, in some embodiments, the spray rate of the silver (Ag) material may be higher in the second condition than in the first condition.

In addition, in FIGS. 5 and 7, although the spray duration of the aluminum material is illustrated up to 80 seconds, the thickness of the common electrode 230 in the first condition and the second condition is the same, and the spray rate of the aluminum material is higher in the second condition than in the first condition, and thus, the final spray duration of the aluminum material is shorter in the second condition than in the first condition.

In other words, in the first condition and the second condition, the thickness of the common electrode 230 and the doping concentration of the aluminum material were the same after deposition is completed, but in terms of the deposition processes associated with the first condition and the second condition, the deposition rate was higher in the second condition than the first condition.

Comparing FIGS. 6 and 8, the concentration of the particles PT formed in the common electrode 230 of FIG. 6 is different from the concentration of the particles PT in the common electrode 230 of FIG. 8. In detail, the concentration of the particles PT formed in the common electrode 230 is higher in the second condition compared to the first condition. That is, when the thickness of the common electrode 230 and the doping concentration of the aluminum material are the same, the particles PT are more effectively formed (e.g., according to a higher concentration) under the second condition in which a faster deposition rate is set, compared to the formation of the particles PT under the first condition.

Aspects of the present disclosure have been described with reference to the example embodiments illustrated in the drawings, but the embodiments are examples, and those skilled in the art will understand that various modifications and variations of the embodiments are possible therefrom. Therefore, the technical scope of protection of the disclosure should be determined by the technical spirit of the appended claims.

According to embodiments of the disclosure, the luminance and WAD characteristics of a display device may be improved through a relatively simple process.

The effects of the disclosure are not limited to the effects mentioned above, and other effects not mentioned will be clearly understood by those skilled in the art from the description of the claims.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a substrate;
a pixel electrode disposed on the substrate;
an intermediate layer disposed on the pixel electrode; and
a common electrode disposed on the intermediate layer,
wherein the common electrode comprises a silver (Ag) material doped with a first metal.

2. The display device of claim 1, further comprising a capping layer disposed on the common electrode.

3. The display device of claim 1, wherein the first metal comprises at least one material among aluminum (Al) and copper (Cu).

4. The display device of claim 1, wherein a doping concentration of the first metal ranges from about 5% to about 20%.

5. The display device of claim 1, wherein a thickness of the common electrode ranges from about 0.01 μm to about 10 μm.

6. The display device of claim 1, wherein the common electrode comprises particles in which the silver (Ag) material and the first metal are combined.

7. The display device of claim 6, wherein a path of light emitted from the intermediate layer is changed as the light is incident the particles.

8. The display device of claim 6, wherein the particles are uniformly distributed in the common electrode.

9. A method of manufacturing a display device, the method comprising:
disposing a pixel electrode on a substrate;
disposing an intermediate layer on the pixel electrode; and
disposing a common electrode on the intermediate layer,
wherein the disposing of the common electrode comprises:
spraying a silver (Ag) material on the intermediate layer; and
spraying a first metal onto the intermediate layer.

10. The method of claim 9, wherein a spray rate of the first metal ranges from about 0.61 Å/s to about 1 Å/s.

11. The method of claim 9, further comprising disposing a capping layer on the common electrode.

12. The method of claim 9, wherein the first metal comprises at least one material among aluminum (Al) and copper (Cu).

13. The method of claim 9, wherein a doping concentration of the first metal ranges from about 5% to about 20%.

14. The method of claim 9, wherein a thickness of the common electrode ranges from about 0.01 μm to about 10 μm.

15. The method of claim 9, wherein the silver (Ag) material and the first metal combine to form particles.

16. The method of claim 15, wherein a path of light emitted from the intermediate layer is changed as the light is incident with the particles.

17. The method of claim 15, wherein the particles are uniformly distributed in the common electrode.
